(19) United States
(12) Patent Application Publication
(10) Pub. No.: US 2026/0247738 A1
(43) Pub. Date: Aug. 20, 2026

(54) DEVICE FOR DISPLAYING IMAGES AND CONVERTING AMBIENT ENERGY INTO ELECTRICAL ENERGY

(71) Applicant: Commissariat à I'Énergie Atomique et aux Énergies Alternatives, Paris (FR)

(72) Inventor: Sébastien Becker, Grenoble (FR)

(21) Appl. No.: 19/540,402

(22) Filed: Feb. 13, 2026

(30) Foreign Application Priority Data
Feb. 20, 2025 (FR) FR2501731

(51) Int. Cl. H10F 55/00

(52) U.S. Cl. CPC H10F 55/00

(57) ABSTRACT

The present description relates to a device (100) comprising: a transfer substrate (101) comprising electrical connection elements (105, 109); a plurality of elementary chips (121) fixed and electrically connected to the transfer substrate (101), each elementary chip (121) comprising at least one LED (125) and an control electronic circuit (123) for said at least one LED (125); at least one element (141) for converting ambient energy into electrical energy, fixed and electrically connected to the transfer substrate (101); and at least one electrical power management circuit (131) fixed and electrically connected to the transfer substrate (101), the electrical power management circuit (131) being configured to optimize electrical power delivered by said at least one conversion element (141) for supplying electrical power to a load.

### TECHNICAL FIELD

The present description generally relates to the field of image display devices and more particularly, to an image display device combining a light emission function and a function for converting ambient energy into electrical energy. The present description also relates to a method for manufacturing such a device.

### Background Art

Image display devices comprising a plurality of elementary monolithic electronic chips arranged in an array on a same transfer substrate have already been proposed, for example in the patent applications WO2017089676, EP3401958 and WO2018185433 previously filed by the applicant. In these devices, the elementary chips are mounted integrally with the transfer substrate and connected to electrical connection elements of the transfer substrate for their control. Each chip comprises one or more light-emitting diodes (LEDs) and a control circuit for said one or more LEDs and corresponds to a pixel of the device. The control circuit comprises a connection face opposite said one or more LEDs, comprising a plurality of electrical connection pads to be connected to the transfer substrate for controlling the microchip. The transfer substrate comprises a connection face comprising, for each microchip, a plurality of electrical connection pads to be connected respectively to the electrical connection pads of the microchip. The chips are transferred on the transfer substrate, with their connection faces facing the connection face of the transfer substrate, and are fixed on the transfer substrate so as to connect the electrical connection pads of each microchip to the corresponding electrical connection pads of the transfer substrate.

This type of display device is particularly suitable for making display screens, for example computer screens, television screens, tablet screens, etc.

In addition, interactive display devices combining a light emission function and a capture or actuation function have been proposed, for example in the patent application FR3125358 previously filed by the applicant.

### SUMMARY OF INVENTION

One embodiment provides a device comprising:
a transfer substrate comprising electrical connection elements;
a plurality of elementary chips fixed and electrically connected to the transfer substrate, each elementary chip comprising at least one LED and a control electronic circuit for said at least one LED;
at least one element for converting ambient energy into electrical energy, fixed and electrically connected to the transfer substrate; and at least one electrical power management circuit fixed and electrically connected to the transfer substrate, the electrical power management circuit being configured to optimize electrical power delivered by said at least one conversion element for supplying electrical power to a load,
   wherein each power management circuit (131) is integrated into the control electronic circuit (123) of at least one of the elementary chips (401).

According to one embodiment, each element for converting ambient energy into electrical energy is a photovoltaic cell.

According to one embodiment, each photovoltaic cell comprises at least one layer (143) for converting photons into electrical charges by photovoltaic effect, selected among:
an inorganic semiconductor layer;
an organic semiconductor layer;
a layer of a perovskite material; and
a matrix layer integrating quantum dots.

According to one embodiment, each element for converting ambient energy into electrical energy is adapted to convert mechanical or thermal energy into electrical energy.

According to one embodiment, at least one of the energy conversion elements utilizes an ambient energy source different from the ambient energy source utilized by the other conversion elements.

According to one embodiment, said at least one element for converting ambient energy into electrical energy is coupled, preferably connected, to said at least one power management circuit.

According to one embodiment, each power management circuit is coupled, preferably connected, to the control electronic circuit of at least one of the elementary chips.

According to one embodiment, each element for converting ambient energy into electrical energy partially covers the control electronic circuit of at least one of the elementary chips.

According to one embodiment, each power management circuit comprises a voltage regulator and a MPPT.

According to one embodiment, each power management circuit is implemented in CMOS technology.

According to one embodiment, each power management circuit comprises an electrical energy storage element, preferably a capacitor, more preferably a MIM, MOM or MIS capacitor.

According to one embodiment, the load consists of at least one of the elementary chips.

According to one embodiment, the load consists of a battery.

One embodiment provides a method for manufacturing a device, the method comprising the following successive steps:
a) providing a transfer substrate comprising electrical connection elements;
b) fixing and electrically connecting to the transfer substrate a plurality of elementary chips each comprising at least one LED and a control electronic circuit for said at least one LED;
c) fixing and electrically connecting to the transfer substrate at least one electrical power management circuit, configured to optimize electrical power delivered by at least one element for converting ambient energy into electrical energy for supplying electrical power to a load; and
d) forming, on the transfer substrate, at least one element for converting ambient energy into electrical energy,
   wherein each power management circuit (131) is integrated into the control electronic circuit (123) of at least one of the elementary chips (401).

### BRIEF DESCRIPTION OF DRAWINGS

The foregoing features and advantages, as well as others, will be detailed in the following description of particular embodiments given on a non-limiting basis with reference to the accompanying drawings, in which:

FIG. 1A, FIG. 1B, FIG. 1C and FIG. 1D are cross-sectional views illustrating successive steps of a method for manufacturing a device for displaying images and converting ambient energy into electrical energy according to one embodiment;

FIG. 2 is a top view of a device for displaying images and converting ambient energy into electrical energy according to one embodiment;

FIG. 3 is a top view of a device for displaying images and converting ambient energy into electrical energy according to one embodiment;

FIG. 4A and FIG. 4B are cross-sectional views illustrating successive steps of a method for manufacturing a device for displaying images and converting ambient energy into electrical energy according to one embodiment; and

FIG. 5 is a top view of a device for displaying images and converting ambient energy into electrical energy according to one embodiment.

### DESCRIPTION OF EMBODIMENTS

The same elements have been designated by the same references in the various Figures. In particular, structural and/or functional elements common to the various embodiments may have the same references and may have identical structural, dimensional and material properties.

For the sake of clarity, only the steps and elements useful for understanding the described embodiments have been illustrated and are detailed. In particular, the various applications of the devices for displaying images and converting ambient energy into electrical energy of the present description have not been detailed, as the described embodiments are compatible with all or most applications of image display devices.

Unless otherwise specified, when reference is made to two elements connected to each other, this means directly connected without any intermediate elements other than conductors and when reference is made to two elements coupled to each other, this means that these two elements may be connected or coupled through one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “higher”, “lower”, etc. or to qualifiers of orientation, such as “horizontal”, “vertical”, etc., reference is made to the orientation of the Figures.

Unless otherwise specified, the expressions “around”, “approximately”, “substantially” and “of the order of” signify within 10 % or 10°, and preferably within 5 % or 5°.

Unless otherwise specified, the terms “insulating” and “conductive” respectively mean electrically insulating and electrically conductive.

Unless otherwise specified, the expression “in contact with” means “in mechanical contact with”.

According to one aspect of an embodiment, an image display device is provided, comprising a plurality of elementary monolithic electronic chips arranged in an array on a same transfer substrate. As in the examples described in the patent applications WO2017089676, EP3401958 and WO2018185433 previously filed by the applicant, the elementary chips are mounted integrally with the transfer substrate and are connected to electrical connection elements of the transfer substrate. Each chip comprises one or more LEDs and a control circuit for said one or more LEDs and corresponds to a pixel of the device. The control circuit comprises a connection face opposite said one or more LEDs, comprising a plurality of electrical connection pads (also called terminals or pillars) to be connected to the transfer substrate for controlling the microchip. The transfer substrate comprises a connection face comprising, for each microchip, a plurality of electrical connection pads (also called terminals or pillars) to be respectively connected to the electrical connection pads of the microchip. The chips are transferred on the transfer substrate, with their connection faces facing the connection face of the transfer substrate, and are fixed to the transfer substrate so as to connect the electrical connection pads of each microchip to the corresponding electrical connection pads of the transfer substrate.

According to one aspect of an embodiment, the image display device further comprises a function for converting ambient energy into electrical energy, for example a function for converting ambient light energy into electrical energy by photoelectric effect.

For this purpose, the device comprises at least one element for converting ambient energy into electrical energy, for example at least one photoelectric conversion element. The element(s) for converting ambient energy into electrical energy is/are arranged on the transfer substrate of the device, on the same side of the transfer substrate as the pixel elementary chips. As a variant, the element(s) for converting ambient energy into electrical energy may be arranged under the transfer substrate of the device, on the side of a face of the transfer substrate opposite to that on which the pixel elementary chips are located. The element(s) for converting ambient energy into electrical energy is/are connected to electrical connection terminals of the transfer substrate for recovery and/or redistribution of the electrical energy produced by these elements. The element(s) for converting ambient energy into electrical energy are to supply electrical power for the purpose of supplying electrical power to at least one load, and not for the purpose of measuring or detecting a signal.

According to one aspect of an embodiment, the image display device further comprises at least one circuit for managing the electrical power produced by the element(s) for converting ambient energy into electrical energy, configured to optimize electrical power delivered for supplying electrical power to a load. As an example, the load may consist of one or more pixel elementary chips of the device. As a variant, the load may consist of one or more electrical energy storage elements, for example a battery, of the device.

Example embodiments of such a display device integrating an energy recovery function are described in more detail below in relation to the Figures.

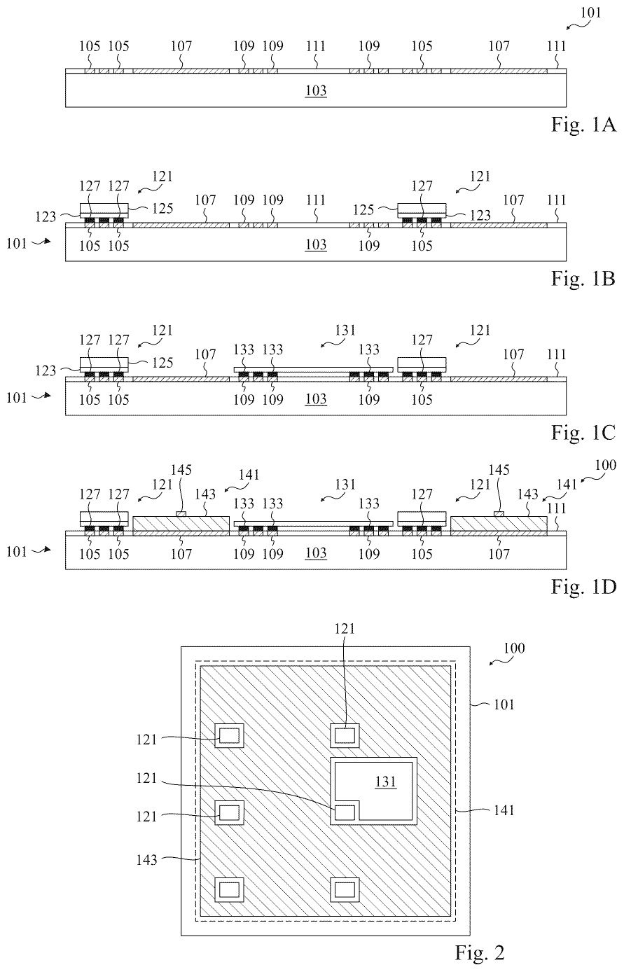

FIG. 1A, FIG. 1B, FIG. 1C and FIG. 1D are cross-sectional views illustrating successive steps of a method for manufacturing a device 100 for displaying images and converting ambient energy into electrical energy according to one embodiment.

FIG. 1A illustrates more particularly an example embodiment of a transfer substrate 101.

The transfer substrate 101 comprises, for example, a support plate or sheet 103 made of an insulating material, for example glass or plastic. As a variant, the support plate or sheet 103 comprises a conductive support, for example metallic, covered with a layer of an insulating material. The transfer substrate 101 further comprises electrical connection elements, and in particular conductive tracks and conductive pads, formed on the upper face of the support plate 103. These electrical connection elements are, for example, formed by printing a succession of conductive and insulating layers on the upper face of the support plate 103. The electrical connection elements are formed, for example, by a deposition or printing method of the types such as inkjet printing, screen printing, rotogravure printing, vacuum deposition, or by any other suitable method.

As an example, the transfer substrate 101 comprises several conductive metallic layers, for example two metallic layers, separated by an insulating layer, and metallic vias connecting the two metallic layers through the insulating layer. In the illustrated example, the transfer substrate 101 further comprises metallic connection pads 105 formed on the upper metallic layer and to be connected to corresponding connection pads of pixel elementary chips of the device 100.

In the illustrated example, the transfer substrate 101 further comprises electrodes 107 of elements for converting ambient energy into electrical energy formed on the upper metallic layer. In the illustrated example, the transfer substrate 101 further comprises metallic connection pads 109 formed on the upper metallic layer and to be connected to corresponding connection pads of a circuit for managing the electrical power produced by the element(s) for converting ambient energy into electrical energy, configured to optimize electrical power delivered for supplying electrical power to a load.

Although this has not been detailed in FIG. 1A so as not to overload the drawing, at least one of the electrodes 107 is coupled, preferably connected, to at least one of the metallic connection pads 109.

In the illustrated example, the upper face of the support plate 103 is coated with an alternation of metallic regions, formed by the metallic connection pads 105 and 109 and by the electrodes 107, and of insulating regions 111, interposed laterally between the metallic regions, so that the transfer substrate 101 has a substantially flat upper face.

FIG. 1B illustrates a step for collectively transferring pixel elementary chips 121 onto the transfer substrate 101.

The elementary chips 121 are, for example, initially fixed to one face of a temporary support substrate (not illustrated). The structure comprising the temporary support substrate and the elementary chips is, for example, produced by a method of the type of the one described in the patent application FR3125358 previously filed by the applicant.

Each elementary chip 121 comprises, for example, an elementary control circuit 123 and one or more LEDs 125, for example three LEDs adapted to respectively emit green light, red light and blue light.

The elementary chips 121 are collectively transferred opposite the connection face of the transfer substrate 101, i.e. its upper face in the orientation of FIGS. 1A to 1D, using the temporary support substrate as a handle.

Connection terminals 127 of the elementary chips 121, located on the side of the lower face of said chips, are then brought into contact with the corresponding connection pads 105 of the transfer substrate 101. The fixation of the connection terminals 127 of the elementary chips 121 to the connection pads 105 of the transfer substrate 101 is, for example, done by direct bonding, thermocompression, soldering, by means of metallic microstructures (e.g. Micro-pillars) previously formed on the terminals 127, or by any other suitable fixation and connection method.

Once fixed to the transfer substrate 101 by their connection terminals 127, the elementary chips 121 are detached from the temporary support substrate and the latter is removed, freeing access to the emitting face of the LEDs.

The pitch of the elementary chips 121 on the transfer substrate 101 may be greater than the pitch of the elementary microchips 121 on the temporary support substrate.

Preferably, the pitch of the elementary chips 121 on the transfer substrate 101 is a multiple of the pitch of the elementary microchips 121 on the temporary support substrate. In this case, only the chips of a part of the chips 121 are removed from the temporary support substrate during each transfer. The other chips 121 remain integral with the temporary support substrate and can be used in another collective transfer step to populate another part of the transfer substrate 101 or another transfer substrate.

FIG. 1C illustrates a step for transferring a power management circuit 131 onto the transfer substrate 101.

The power management circuit 131 is, for example, initially fixed to one face of a temporary support substrate (not illustrated).

The power management circuit 131 comprises, for example, a voltage regulator and a MPPT (Maximum Power Point Tracking). The power management circuit 131 is, for example, of the PMU (Power Management Unit) type. The power management circuit 131 is, for example, implemented in CMOS (Complementary Metal-Oxide-Semiconductor) technology. As an example, the power management circuit 131 is of the type of the one described in the publication by F. Galea et al. entitled “An Ultra-Low Power CMOS MPPT Power Conditioning Circuit for Energy Harvesters”, 2020 IEEE International Symposium on Circuits and Systems (ISCAS).

The power management circuit 131 is transferred opposite the connection face of the transfer substrate 101, using the temporary support substrate as a handle.

Connection terminals 133 of the power management circuit 131, located on the side of the lower face of the circuit, are then brought into contact with the corresponding connection pads 109 of the transfer substrate 101. The fixation of the connection terminals 133 of the power management circuit 131 to the connection pads 109 of the transfer substrate 101 is, for example, done in a manner similar to that above described for the fixation of the connection terminals 127 of the chips 121 to the connection pads 105.

Once fixed to the transfer substrate 101 by its connection terminals 133, the power management circuit 131 is detached from the temporary support substrate and the latter is removed.

Although FIG. 1C illustrates the transfer of a single power management circuit 131 onto the transfer substrate 101, this example is not limiting, as several circuits 131 may of course be transferred simultaneously or successively onto the transfer substrate 101 during this step.

At the end of the step of FIG. 1C, the electrodes 107 are coupled, preferably connected, to the connection terminals 133 of the power management circuit(s) 131.

FIG. 1D illustrates a step for forming elements 141 for converting ambient energy into electrical energy on the transfer substrate 101.

During this step, for example, a portion of at least one conversion layer 143, or active layer, is deposited, for each element 141 for converting ambient energy into electrical energy, on and in contact with the upper face of the corresponding electrode 107. The layer 143 is, for example, a semiconductor layer for converting photons into electrical charges by photoelectric effect, for example by photovoltaic effect. In each conversion element 141, the portion of the layer 143 extends, for example, over the entire upper face of the underlying electrode 107. The electrode 107 constitutes, for example, a lower electrode of the element 141. As an example, the conversion layer 143 has a thickness of the order of 1 um.

During the step of FIG. 1D, an upper electrode 145, located on and in contact with the upper face of the portion of the layer 143, is also deposited, for each element 141 for converting ambient energy into electrical energy,.

Although this has not been detailed in FIG. 1D so as not to overload the drawing, the electrodes 145 are, for example, coupled, preferably connected, to at least one of the connection terminals 133 of the power management circuit(s) 131.

At the end of the step of FIG. 1D, each element 141 for converting ambient energy into electrical energy is coupled, preferably connected, to the power management circuit 131 or to one of the power management circuits 131.

In general, each element 141 for converting ambient energy into electrical energy can be adapted to convert any type of energy, for example light energy, heat energy, mechanical energy, etc., into electrical energy. The electrical energy thus produced is to supply electrical power to a load internal or external to the device 100. For example, the conversion elements 141 all use the same ambient energy source. As a variant, at least one of the conversion elements 141 may use an ambient energy source different from the ambient energy source used by the other conversion elements 141.

In particular, at least one of the conversion elements 141 is, for example, a photovoltaic cell, or solar cell, to convert ambient light energy, for example radiation emitted by the sun, into electrical energy by photoelectric effect. In this case, the conversion layer 143 is more particularly a photoconversion layer to convert incident photons into electron-hole pairs. Furthermore, in this case, the electrode 145 is transparent to the wavelengths to which the layer 143 is sensitive. As an example, the electrode 145 is made of a conductive and transparent oxide, for example indium tin oxide (ITO).

As an example, the conversion elements 141 of the device 100 are based on inorganic semiconductor materials, for example based on amorphous silicon, polysilicon, perovskites, III-V semiconductor materials, for example indium gallium arsenide, II-VI semiconductor materials, for example cadmium telluride, etc. As a variant, the inorganic conversion elements 141 of the device 100 may be replaced by conversion elements based on organic materials or comprising a matrix layer, for example made of resin, in which quantum dots are incorporated.

An example embodiment in which the conversion elements 141 are photoelectric transducers has been described above. However, this example is not limiting. As a variant or in addition, at least one of the conversion elements 141 is a thermoelectric, electromechanical, electromagnetic transducer, etc. The implementation and the integration of this or these transducers is within the reach of those skilled in the art based on the indications of the present description. Furthermore, although an example embodiment has been described in which the conversion elements 141 are formed by deposition on the transfer substrate 101, this example is not limiting and all or part of the conversion elements 141 may, as a variant, be produced in the form of discrete components transferred on the transfer substrate 101 in a manner analogous to that described above for the power management circuit(s) 131 and for the elementary chips 121.

In a case where the layer 143 is made of an organic material, the portions of the layer 143 are, for example, deposited by a localized printing method, for example by screen printing or by a slot-die coating method.

FIG. 2 is a top view of the device 100 for displaying images and converting ambient energy into electrical energy. For drawing readability purposes, the upper electrode of the element 141 for converting ambient energy into electrical energy has not been illustrated in FIG. 2.

In the illustrated example, the device 100 comprises a single conversion element 141 for a group of six neighboring elementary chips 121. In this example, the conversion layer 143 of the element 141 extends laterally between the elementary chips 121. Furthermore, in the illustrated example, the conversion element 141 is associated with a single power management circuit 131. However, this example is not limiting, as the device 100 may more generally comprise any proportions and numbers of elementary chips 121, of conversion elements 141 and of power management circuits 131. As an example, the device 100 comprises a number of elementary chips 121 strictly greater than the number of conversion elements 141, preferably an integer multiple of the number of elements 141. As an example, the device 100 comprises two, four, six, nine or sixteen times more chips 121 than elements 141. However, this example is not limiting, as the device 100 may, as a variant, comprise a single conversion element 141, a single power management circuit 131 and several thousand or million chips 121, for example in the case of a smartwatch screen or of a mobile phone screen, for example of a smartphone. In addition, the device 100 comprises, for example, a number of power management circuits 131 equal to the number of conversion elements 141. As a variant, the number of circuits 131 may be strictly less than the number of elements 141, in which case several elements 141 are coupled or connected to a same circuit 131.

The conversion elements 141 are, for example, dimensioned, for example in terms of surface area, to produce a voltage compatible with a maximum voltage allowable by the associated power management circuit 131. As an example, the allowable maximum voltage is in the range of 1.8 to 5 V, for example equal to approximately 3.3 V, in the case where the circuit 131 is made using CMOS technology. However, this example is not limiting, as the allowable maximum voltage may, as a variant, be greater than 5 V, or even greater than 10 V.

As an example, the power management circuit 131 may integrate a function for storing electrical charges produced by the element 141 for converting ambient energy into electrical energy. In this case, the circuit 131 comprises, for example, one or more electrical energy storage elements such as capacitive elements, for example capacitors, for example of the MIM (Metal-Insulator-Metal), MOM (Metal-Oxide-Metal) or MIS (Metal-Insulator-Semiconductor) type. As a variant, the power management circuit 131 may be coupled or connected to an energy storage element external to the circuit 131, for example a battery or any other type of electrical circuit peripheral to the device 100.

Although FIGS. 1D and 2 illustrate an example embodiment in which the power management circuit 131 is integrated into the emissive matrix formed by the elementary chips 121 of the device 100, this example is not limiting and the circuit 131 may, as a variant, be disposed at the periphery of the emissive matrix. In the illustrated example where the circuit 131 is integrated into the emissive matrix, the circuit 131 advantageously has maximum lateral dimensions strictly less than the pitch of the pixel elementary chips 121 on the transfer substrate 101. As an example, the power management circuit 131 has a maximum lateral dimension of the order of 100 μm.

The device 100 has the advantage of combining a function for displaying images and a function for converting ambient energy into electrical energy. Advantageously, this makes possible, for example, to reduce or even eliminate the need for an external electrical power supply for an electronic apparatus incorporating the device 100. As an example, said electronic apparatus has no external electrical power supply, as the element(s) 141 for converting ambient energy into electrical energy of the device 100 are to power supply all of the electrical energy consumed by the elementary chips 121. In this case, at least one of the connection terminals 133 of the power management circuit 131 is coupled, preferably connected, to one of the connection terminals 127 of at least one of the elementary chips 121 of the device 100. This makes possible, for example, the device 100 constitutes an energy-autonomous image display device i.e. that does not need to be coupled to an electrical network.

The fact of planning that the power management circuit 131 is to supply electrical power to one or more elementary chips 121, for example elementary chips 121 neighboring to the circuit 131, also has the advantage of reducing Joule effect losses.

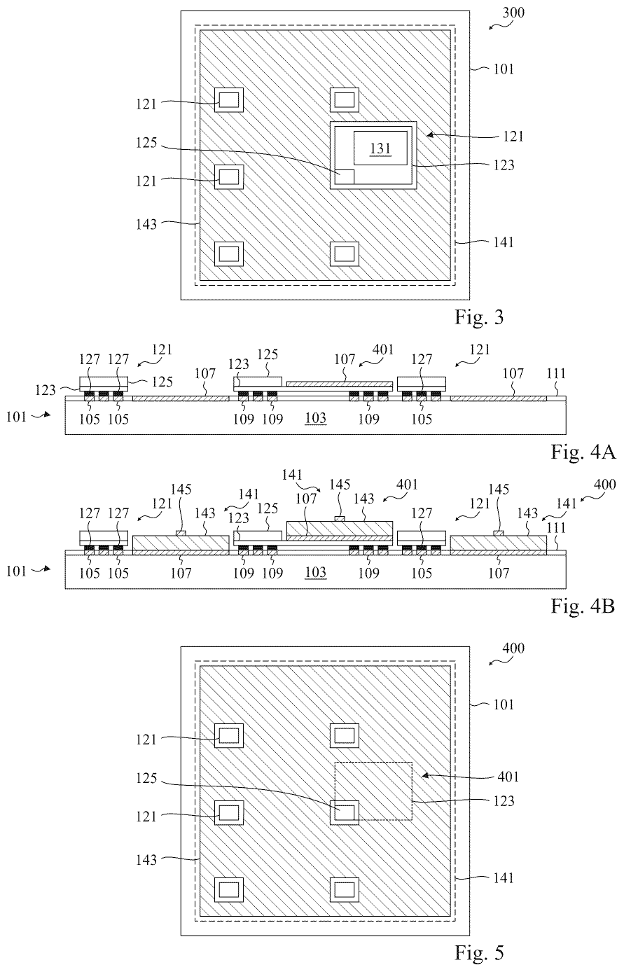

FIG. 3 is a top view of a device 300 for displaying images and converting ambient energy into electrical energy according to one embodiment. For drawing readability purposes, the upper electrode of the element 141 for converting ambient energy into electrical energy has not been illustrated in FIG. 3.

FIG. 3 illustrates more particularly an embodiment in which the electronic circuit 123 of one of the elementary chips 121 comprises the power management circuit 131. In other words, the circuit 131 is integrated into the circuit 123 of one of the chips 121.

One advantage of the device 300 is that it makes possible to take advantage of the presence of the electronic circuit 123 of one of the elementary chips 121 to integrate the power management circuit 131 configured to optimize electrical power supplied by the conversion element 141 to which it is coupled or connected into electrical power for supplying a load, for example, electrical power for supplying the elementary chip 121 integrating the circuit 131 and five other neighboring elementary chips 121, in the illustrated example.

FIG. 4A and FIG. 4B are cross-sectional views illustrating successive steps of a method for manufacturing, based on the structure previously described in relation to FIG. 1B, a device 400 for displaying images and converting ambient energy into electrical energy according to one embodiment.

FIG. 4A illustrates more particularly a step for transferring an elementary chip 401 onto the transfer substrate 101.

The elementary chip 401 differs, for example, from the elementary chips 121 in that the elementary control circuit 123 of the elementary chip 401 integrates the power management circuit 131 (not detailed in FIGS. 4A and 4B).

Furthermore, in the example illustrated in FIG. 4A, an electrode 107 is formed on the upper face of the elementary control circuit 123 of the elementary chip 401. As an example, the electrode 107 of the chip 401 covers substantially the entire upper face of the circuit 123 not covered by the LED(s) 125.

FIG. 4B illustrates a subsequent step for forming elements 141 for converting ambient energy into electrical energy on the transfer substrate 101 and on the chip 401. The step of FIG. 4B is, for example, analogous to the step previously described in relation to FIG. 1D.

FIG. 5 is a top view of the device 400 for displaying images and converting ambient energy into electricity. For drawing readability purposes, the upper electrode of the element 141 for converting ambient energy into electricity has not been illustrated in FIG. 5.

In the illustrated example, a part of the conversion element 141 covers the elementary control circuit 123 of the elementary chip 401.

The device 400 has the advantage of making possible the conversion element 141 to occupy a larger surface area compared to the devices 200 and 300. For the same amount of ambient energy, the device 400 is thus capable of supplying an amount of electrical energy greater than that supplied by the devices 100 and 300.

Although not illustrated, the conversion element 141 may, in the case of a photovoltaic conversion element, be coplanar with the emissive elements 125 of the elementary chips. As a variant, the conversion element 141 may be disposed in front of the emissive elements 125, for example in a case where the element 141 forms a transparent solar cell in the emission range of the elementary chips for displaying images. As a variant, the conversion element 141 may be disposed under the emissive elements 125, for example by providing connections on the front face of the conversion element 141 for controlling the LEDs 125, or even on the rear face of the transfer substrate 101, for example by providing electrical connection elements, for example conductive vias, between the front and rear faces of the substrate 101.

Furthermore, although not illustrated in the Figures, at least one of the pixel elementary chips can be used to control one or more other elements external to the elementary chip, for example, selected among a photodetector, an ultrasonic or acoustic transducer, a VCSEL (Vertical-Cavity Surface-Emitting Laser, i.e. a laser diode with a vertical cavity emitting by the surface). This makes possible, for example, to implement detection functions for detecting the touch or the proximity of an object, for example a user's hand, for example by using the direct piezoelectric effect, and/or haptic stimulation functions, and/or directional acoustic wave emission functions, for example by using the indirect piezoelectric effect.

Various embodiments and variants have been described. Those skilled in the art will understand that certain features of these various embodiments and variants could be combined, and other variants will readily occur to those skilled in the art. In particular, the described embodiments are not limited to the particular examples of implementation of the pixel elementary chips and of the transfer substrate 101 described in relation to FIGS. 1A to 1D, 2, 3, 4A, 4B and 5.

Finally, the practical implementation of the described embodiments and variants is within the reach of those skilled in the art based on the hereinabove provided functional indications. In particular, the described embodiments are not limited to the particular examples of materials and dimensions mentioned in the present description.

1. A device (100; 300; 400) comprising:
a transfer substrate (101) comprising electrical connection elements (105, 109);
a plurality of elementary chips (121; 401) fixed and electrically connected to the transfer substrate (101), each elementary chip (121; 401) comprising at least one LED (125) and a control electronic circuit (123) for said at least one LED (125);
at least one element (141) for converting ambient energy into electrical energy, fixed and electrically connected to the transfer substrate (101); and
at least one electrical power management circuit (131) fixed and electrically connected to the transfer substrate (101), the electrical power management circuit (131) being configured to optimize electrical power delivered by said at least one conversion element (141) for supplying electrical power to a load, wherein each power management circuit (131) is integrated into the control electronic circuit (123) of at least one of the elementary chips (401).

2. The device (100; 300; 400) according to claim 1, wherein each element (141) for converting ambient energy into electrical energy is a photovoltaic cell.

3. The device (100; 300; 400) according to claim 2, wherein each photovoltaic cell comprises at least one layer (143) for converting photons into electrical charges by photovoltaic effect, selected among:
an inorganic semiconductor layer;
an organic semiconductor layer;
a layer of a perovskite material; and
a matrix layer integrating quantum dots.

4. The device (100; 300; 400) according to claim 1, wherein each element (141) for converting ambient energy into electrical energy is adapted to convert mechanical or thermal energy into electrical energy.

5. The device according to claim 1, wherein at least one of the energy conversion elements (141) utilizes an ambient energy source different from the ambient energy source utilized by the other conversion elements (141).

6. The device (100; 300; 400) according to claim 1, wherein said at least one element (141) for converting ambient energy into electrical energy is coupled, preferably connected, to said at least one power management circuit (131).

7. The device (100) according to claim 1, wherein each power management circuit (131) is coupled, preferably connected, to the control electronic circuit (123) of at least one of the elementary chips (121).

8. The device (100; 300; 400) according to claim 1, wherein each element (141) for converting ambient energy into electrical energy partially covers the control electronic circuit (123) of at least one of the elementary chips (121; 401).

9. The device (100; 300; 400) according to claim 1, wherein each power management circuit (131) comprises a voltage regulator and a MPPT.

10. The device (100; 300; 400) according to claim 1, wherein each power management circuit (131) is implemented in CMOS technology.

11. The device (100; 300; 400) according to claim 1, wherein each power management circuit (131) comprises an electrical energy storage element, preferably a capacitor, more preferably a MIM, MOM or MIS capacitor.

12. The device (100; 300; 400) according to claim 1, wherein the load consists of at least one of the elementary chips (121; 401).

13. The device (100; 300; 400) according to claim 1, wherein the load consists of a battery.

14. A method for manufacturing a device (100; 300; 400), the method comprising the following successive steps:
a) providing a transfer substrate (101) comprising electrical connection elements (105; 109);
b) fixing and electrically connecting to the transfer substrate (101) a plurality of elementary chips (121; 401) each comprising at least one LED (125) and a control electronic circuit (123) for said at least one LED (125);
c) fixing and electrically connecting to the transfer substrate (101) at least one electrical power management circuit (131), configured to optimize electrical power delivered by at least one element (141) for converting ambient energy into electrical energy for supplying electrical power to a load; and
d) forming, on the transfer substrate (101), at least one element (141) for converting ambient energy into electrical energy, wherein each power management circuit (131) is integrated into the control electronic circuit (123) of at least one of the elementary chips (401).
